(19) United States
(12) Patent Application Publication
(10) Pub. No.: US 2014/0369103 A1
(43) Pub. Date: Dec. 18, 2014

(54) CONTENT ADDRESSABLE MEMORY CELLS AND TERNARY CONTENT ADDRESSABLE MEMORY CELLS

(71) Applicant: Mediatek Inc., Hsin-Chu (TW)

(72) Inventor: Shu-Hsuan Lin, Hsinchu City (TW)

(21) Appl. No.: 13/917,662

(22) Filed: Jun. 14, 2013

(51) Int. Cl. G11C 15/04

(52) U.S. Cl. CPC G11C 15/04
USPC 365/49.17

(57) ABSTRACT

An embodiment of the invention provides a binary CAM cell. The binary CAM cell includes a storage circuit, a first discharging circuit, and a second discharging circuit. The storage circuit is configured to provide a first stored bit and a second stored bit, which are complimentary bits of each other. The first discharging circuit is configured to either discharge or not discharge a match line according to the first stored bit provided by the storage circuit and a first searched bit provided by a first search line. The first discharging circuit includes a first PMOS transistor. The second discharging circuit is configured to either discharge or not discharge the match line according to the second stored bit provided by the storage circuit and a second searched bit provided by a second search line. The second discharging circuit includes a second PMOS transistor.

### BACKGROUND

1. Technical Field

The invention relates generally to memory, and more particularly, to content addressable memory.

2. Related art

Content addressable memory (CAM) is a type of memory especially suitable for high speed applications. Each basic storage unit of this kind of memory may be referred to as a CAM cell, e.g. a binary CAM cell or a ternary CAM (TCAM) cell. A binary CAM cell may store a bit of data, which is either “0” or “1”. Being able to store two bits of data, a TCAM cell may be at one of three possible states, including “0,” “1,” and “don't care.”

A common problem many manufacturers of CAM memory encounter is that their CAM memory consumes too much power in performing search operations and does not have optimal search speeds.

### SUMMARY

An embodiment of the invention provides a TCAM cell. The TCAM cell includes a first storage circuit, a first discharging circuit, a second storage circuit, and a second discharging circuit. The first storage circuit is configured to provide a first stored bit. The first discharging circuit is coupled to the first storage circuit, a first search line, and a match line, and is configured to either discharge or not discharge the match line according to the first stored bit provided by the first storage circuit and a first searched bit provided by the first search line. The first discharging circuit includes a first PMOS transistor, which has a gate coupled to receive one of the first stored bit and the first searched bit. The second storage circuit is configured to provide a second stored bit. The second discharging circuit is coupled to the second storage circuit, a second search line, and the match line, and is configured to either discharge or not discharge the match line according to the second stored bit provided by the second storage circuit and a second searched bit provided by the second search line. The second discharging circuit includes a second PMOS transistor, which has a gate coupled to receive one of the second stored bit and the second searched bit.

Another embodiment of the invention provides a binary CAM cell. The binary CAM cell includes a storage circuit, a first discharging circuit, and a second discharging circuit. The storage circuit is configured to provide a first stored bit and a second stored bit, wherein the second stored bit is a complimentary bit of the first stored bit. The first discharging circuit is coupled to the storage circuit, a first search line, and a match line, and is configured to either discharge or not discharge the match line according to the first stored bit provided by the storage circuit and a first searched bit provided by the first search line. The first discharging circuit includes a first PMOS transistor, which has a gate coupled to receive one of the first stored bit and the first searched bit. The second discharging circuit is coupled to the storage circuit, a second search line, and the match line, and is configured to either discharge or not discharge the match line according to the second stored bit provided by the storage circuit and a second searched bit provided by the second search line. The second discharging circuit includes a second PMOS transistor, which has a gate coupled to receive one of the second stored bit and the second searched bit.

Other features of the present invention will be apparent from the accompanying drawings and from the detailed description which follows.

### BRIEF DESCRIPTION OF THE DRAWINGS

The invention is fully illustrated by the subsequent detailed description and the accompanying drawings, in which like references indicate similar elements.

FIG. 1 shows a simplified block diagram of a binary CAM cell according to an embodiment of the invention.

FIG. 2 shows a simplified block diagram of a TCAM cell according to an embodiment of the invention.

FIG. 3 to FIG. 8 shows several exemplary embodiments of the discharging circuits of FIG. 1 and FIG. 2.

### DETAILED DESCRIPTION

In the following paragraphs explaining embodiments of the invention, an index used to indicate a line on a circuit may also be used to refer to the logic value corresponding to the voltage level of the line.

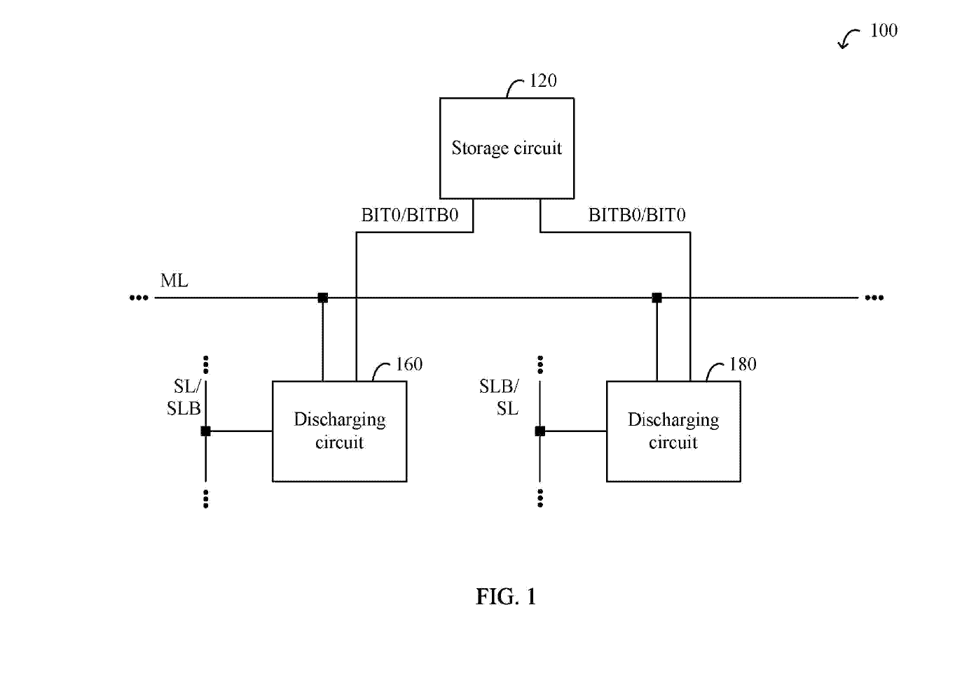

FIG. 1 shows a simplified block diagram of a binary CAM cell according to an embodiment of the invention. For the sake of simplicity, circuits for reading and writing the binary CAM cell 100 are not depicted in FIG. 1.

The binary CAM cell 100 and other binary CAM cells not depicted in the figure may form a two dimensional array of a plurality of rows and a plurality of columns. The binary CAM cell 100 of this embodiment has a storage circuit 120, a discharging circuit 160, and a discharging circuit 180. The discharging circuit 160 and the discharging circuit 180 together may be referred to as a search circuit. The storage circuit 120 has a stored bit BIT0 and s stored bit BITB0, which are complimentary bits of each other. In other words, one of the stored bits BIT0 and BITB0 is binary “0” while the other is binary “1.”

In FIG. 1, the discharging circuit 160 and the discharging circuit 180 are coupled to the storage circuit 120 to receive one and the other of the stored bits BIT0 and BITB0, respectively. Specifically, the discharging circuit 160 and the discharging circuit 180 either receive the stored bit BIT0 and the stored bit BITB0, respectively, or receive the stored bit BITB0 and the stored bit BIT0, respectively.

The discharging circuit 160 is coupled to a search line, which is either SL or SLB, and a match line ML. Based on the searched bit SL/SLB that the coupled search line provides and the stored bit BIT0/BITB0 that the storage circuit 120 provides, the discharging circuit 160 either discharges or not discharges the match line ML. The discharging circuit 160 includes at least one p-channel metal oxide semiconductor (PMOS) transistor. In addition to the at least one PMOS transistor, the discharging circuit 160 may further includes any number of n-channel metal oxide semiconductor (NMOS) transistors.

The discharging circuit 180 is coupled to one search line, which is either SLB or SL, and the match line ML. The two search lines SL and SLB have complimentary binary values; one is “0” while the other is “1.” One of the two search lines SL and SLB is coupled to the discharging circuit 160 while the other is coupled to the discharging circuit 180. Based on the searched bit SLB/SL that the coupled search line provides and the stored bit BITB0/BIT0 that the storage circuit 120 provides, the discharging circuit 180 either discharges or not discharges the match line ML. The discharging circuit 180 includes at least one PMOS transistor. In addition to the at least one PMOS transistor, the discharging circuit 180 may further includes any number of NMOS transistors.

The binary CAM cell 100 shares the search lines SL and SLB with other binary CAM cells on the same column, and shares the match line ML with other binary CAM cells on the same row. To perform a search operation, the match line ML will first be pre-charged to a high voltage level, which may be substantially equal to a drain voltage VDD. Then, the binary CAM cell 100 will determine whether the stored bits BIT0 and BITB0 and the searched bits SL and SLB indicate a hit or a miss. If there is a miss, either or both the discharging circuits 160 and 180 will discharge the match line ML to a low voltage level, which may be substantially equal to the drain voltage VDD minus a threshold voltage Vth. The threshold voltage Vth is a threshold voltage of PMOS transistors within the discharging circuits 160 and 180. On the other hand, if there is a hit, neither the discharging circuit 160 nor the discharging circuit 180 will discharge the match line ML.

Because the match line ML is shared, if at least one of the binary CAM cells sharing the match line ML has a miss, the at least one binary CAM cell will discharge the match line ML to a low voltage level substantially equal to VDD−Vth. Only if all of the binary CAM cells sharing the match line ML have hits will the match line ML maintain the high voltage level substantially equal to VDD.

Because each of the discharging circuits 160 and 180 includes at least one PMOS transistor, if the binary CAM cell 100 has a miss, the two circuits 160 and 180 will discharge the match line ML to the low voltage level substantially equal to VDD−Vth but not lower. In contrast, if the discharging circuits 160 and 180 included only NMOS transistors but no PMOS transistors, the two circuits 160 and 180 would discharge the match line ML to a low voltage level substantially equal to a source voltage VSS, which is much lower than VDD−Vth.

To perform a next search operation, the match line ML will again be pre-charged from at least the low voltage level substantially equal to VDD−Vth, rather than from the much lower VSS, to the high voltage level substantially equal to VDD. Apparently, it generally requires less power to pre-charge the match line ML. This means that the binary CAM cell 100 generally consumes less power in performing search operations. In addition, the binary CAM cell 100 generally needs less time to pre-charge the match line ML, meaning that the binary CAM cell 100 may have a faster speed in performing search operations.

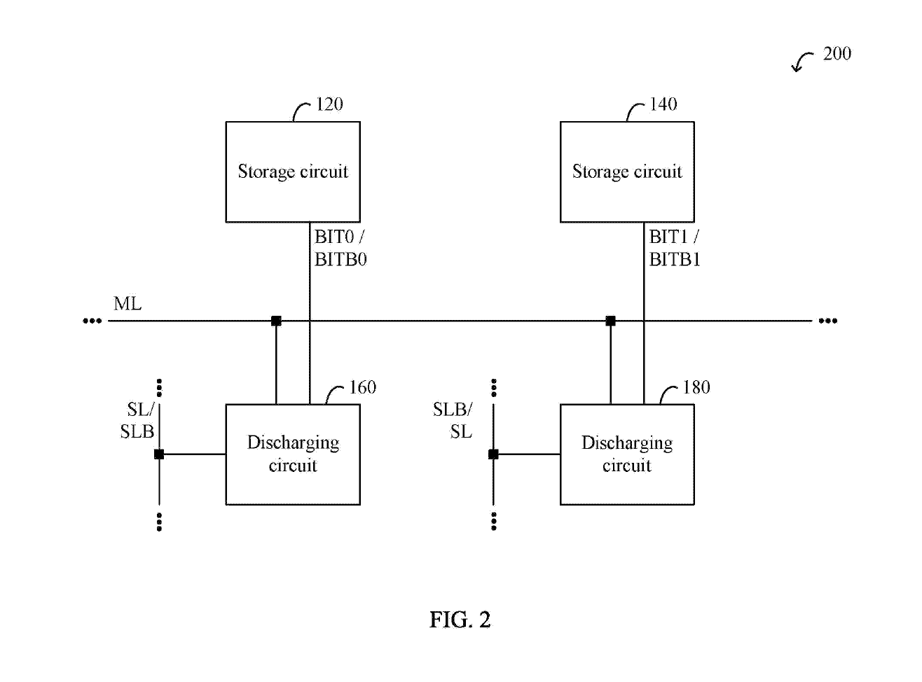

FIG. 2 shows a simplified block diagram of a TCAM cell according to an embodiment of the invention. Similar to the binary CAM cell 100 of FIG. 1, the TCAM cell 200 of FIG. 2 also includes the storage circuit 120, the discharging circuit 160, and the discharging circuit 180. But different from the binary CAM cell 100, the TCAM cell 200 further includes a storage circuit 140. The storage circuit 140 has a stored bit BIT1 and a stored bit BITB1, which are complimentary bits of each other. In other words, one of the stored bits BIT1 and BITB1 is binary “0” while the other is binary “1.” Rather than receiving a stored bit BIT0/BITB0 from the storage circuit 120, the discharging circuit 180 of FIG. 2 receives a stored bit BIT1/BITB1 from the storage circuit 140. Based on the searched bit SLB/SL that the coupled search line provides and the stored bit BIT1/BITB1 that the storage circuit 140 provides, the discharging circuit 180 either discharges or not discharges the match line ML in a search operation. Although the searched bits SL and SLB depicted in FIG. 2 generally are complimentary bits of each other, they may be forced to have the same binary value if whatever stored in this TCAM cell 200 is not concerned in the search operation. Except for these differences, the TCAM cell 200 of FIG. 2 is very similar to the binary CAM cell 100 of FIG. 1 and also has the above-mentioned advantages of the binary CAM cell 100, at least in terms of power saving and speed enhancement.

The discharging circuit 160 of FIG. 1/2 may be realized by two MOS transistors, at least one of which is a PMOS transistor. One of these two MOS transistors may have a gate coupled to receive the stored bit BIT0/BITB0 from the storage circuit 120. The other MOS transistor may have a gate coupled to receive the searched bit SL/SLB from the coupled search line. Similarly, the discharging circuit 180 of FIG. 1/2 may be realized by two MOS transistors, at least one of which is a PMOS transistor. One of these two MOS transistors may have a gate coupled to receive the stored bit BITB0/BIT0 from the storage circuit 120 of FIG. 1 or the stored bit BIT1/BITB1 from the storage circuit 140 of FIG. 2. The other MOS transistor may have a gate coupled to receive the searched bit SLB/SL from the coupled search line.

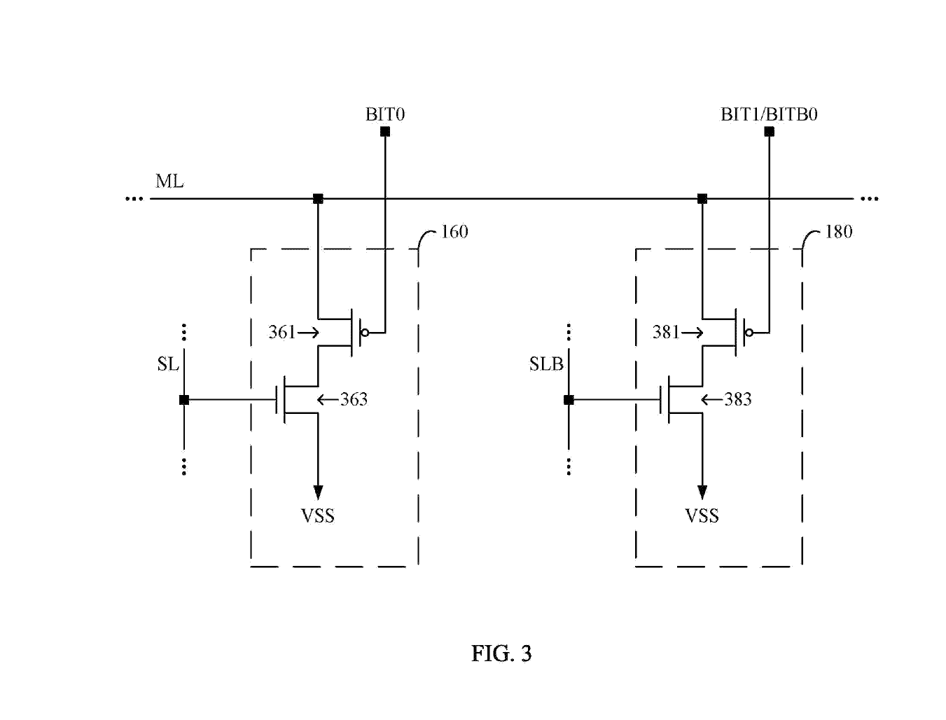

FIG. 3 to FIG. 8 shows several exemplary embodiments of the discharging circuits 160 and 180 of FIG. 1 and FIG. 2. In the example shown in FIG. 3, the discharging circuit 160 includes a PMOS transistor 361 and an NMOS transistor 363, and the discharging circuit 180 includes a PMOS transistor 381 and an NMOS transistor 383. The PMOS transistor 361 has a source coupled to the match line ML, a gate coupled to receive the stored bit BIT0, and a drain coupled to a drain of the NMOS transistor 363. The NMOS transistor 363 has a gate coupled to receive the searched bit SL and a source coupled to the source voltage VSS. Similarly, the PMOS transistor 381 has a source coupled to the match line ML, a gate coupled to receive the stored bit BIT1/BITB0, and a drain coupled to a drain of the NMOS transistor 383. The NMOS transistor 383 has a gate coupled to receive the searched bit SLB and a source coupled to the source voltage VSS.

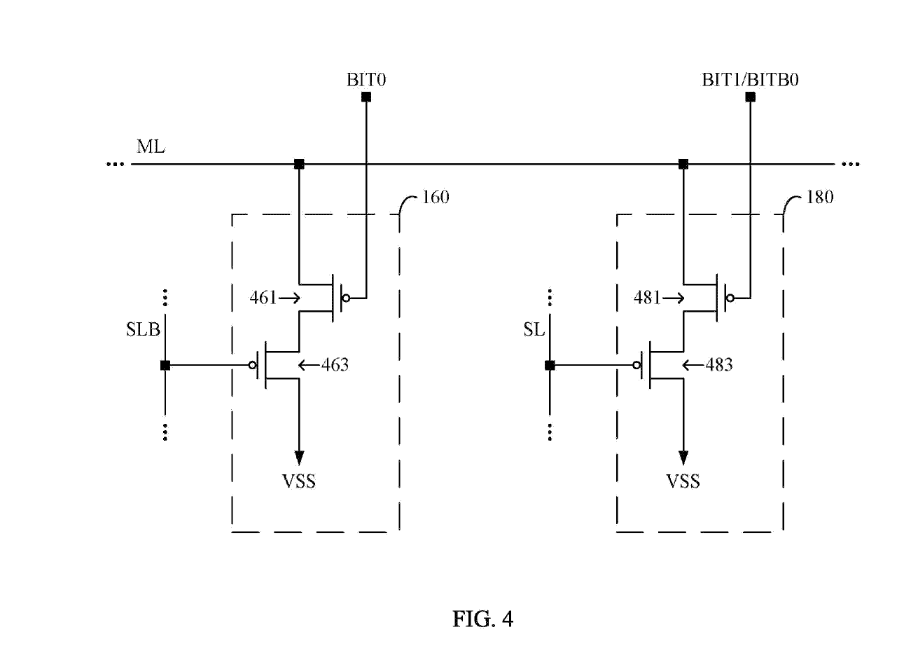

In the example shown in FIG. 4, the discharging circuit 160 includes a PMOS transistor 461 and a PMOS transistor 463, and the discharging circuit 180 includes a PMOS transistor 481 and a PMOS transistor 483. The PMOS transistor 461 has a source coupled to the match line ML, a gate coupled to receive the stored bit BIT0, and a drain coupled to a source of the PMOS transistor 463. The PMOS transistor 463 has a gate coupled to receive the searched bit SLB and a drain coupled to the source voltage VSS. Similarly, the PMOS transistor 481 has a source coupled to the match line ML, a gate coupled to receive the stored bit BIT1/BITB0, and a drain coupled to a source of the PMOS transistor 483. The PMOS transistor 483 has a gate coupled to receive the searched bit SL and a drain coupled to the source voltage VSS.

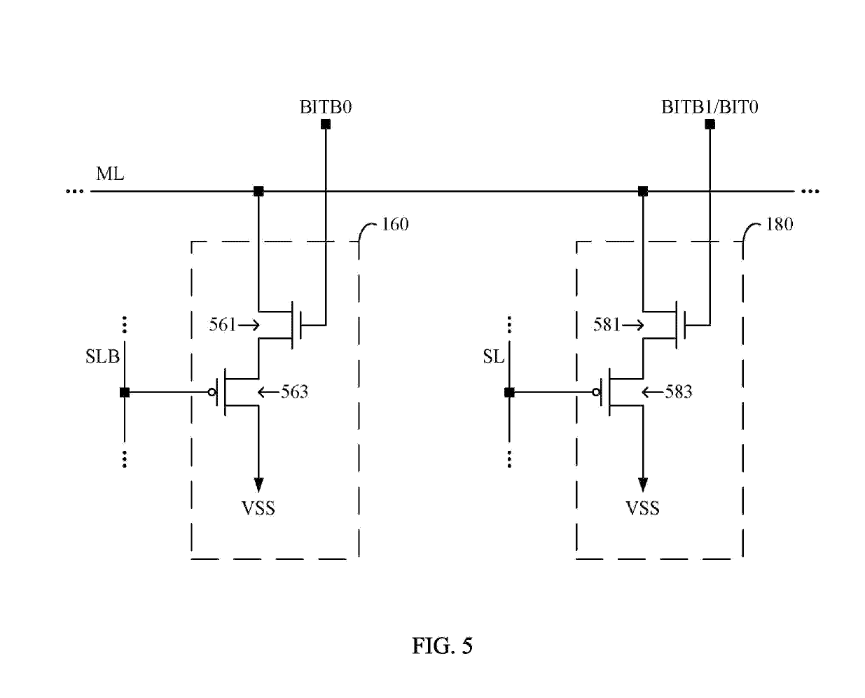

In the example shown in FIG. 5, the discharging circuit 160 includes an NMOS transistor 561 and a PMOS transistor 563, and the discharging circuit 180 includes an NMOS transistor 581 and a PMOS transistor 583. The NMOS transistor 561 has a drain coupled to the match line ML, a gate coupled to receive the stored bit BITB0, and a source coupled to a source of the PMOS transistor 563. The PMOS transistor 563 has a gate coupled to receive the searched bit SLB and a drain coupled to the source voltage VSS. Similarly, the NMOS transistor 581 has a drain coupled to the match line ML, a gate coupled to receive the stored bit BITB1/BIT0, and a source coupled to a source of the PMOS transistor 583. The PMOS transistor 583 has a gate coupled to receive the searched bit SL and a drain coupled to the source voltage VSS.

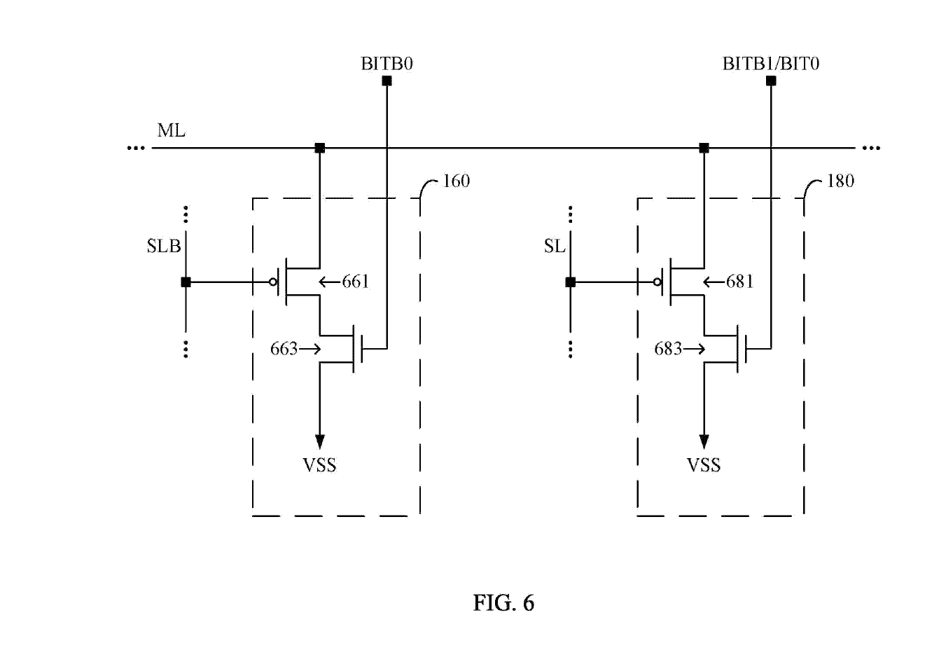

In the example shown in FIG. 6, the discharging circuit 160 includes a PMOS transistor 661 and an NMOS transistor 663, and the discharging circuit 180 includes a PMOS transistor 681 and an NMOS transistor 683. The PMOS transistor 661 has a source coupled to the match line ML, a gate coupled to receive the searched bit SLB, and a drain coupled to a drain of the NMOS transistor 663. The NMOS transistor 663 has a gate coupled to receive the stored bit BITB0 and a source coupled to the source voltage VSS. Similarly, the PMOS transistor 681 has a source coupled to the match line ML, a gate coupled to receive the searched bit SL, and a drain coupled to a drain of the NMOS transistor 683. The NMOS transistor 683 has a gate coupled to receive the stored bit BITB1/BIT0 and a source coupled to the source voltage VSS.

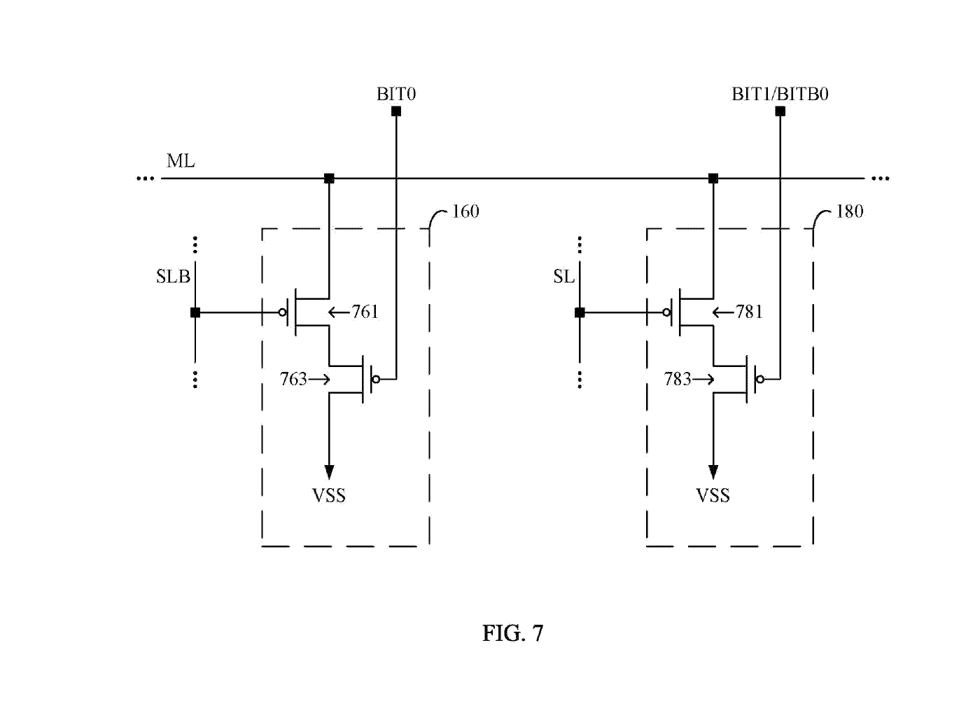

In the example shown in FIG. 7, the discharging circuit 160 includes a PMOS transistor 761 and a PMOS transistor 763, and the discharging circuit 180 includes a PMOS transistor 781 and a PMOS transistor 783. The PMOS transistor 761 has a source coupled to the match line ML, a gate coupled to receive the searched bit SLB, and a drain coupled to a source of the PMOS transistor 763. The PMOS transistor 763 has a gate coupled to receive the stored bit BIT0 and a drain coupled to the source voltage VSS. Similarly, the PMOS transistor 781 has a source coupled to the match line ML, a gate coupled to receive the searched bit SL, and a drain coupled to a source of the PMOS transistor 783. The PMOS transistor 783 has a gate coupled to receive the stored bit BIT1/BITB0 and a drain coupled to the source voltage VSS.

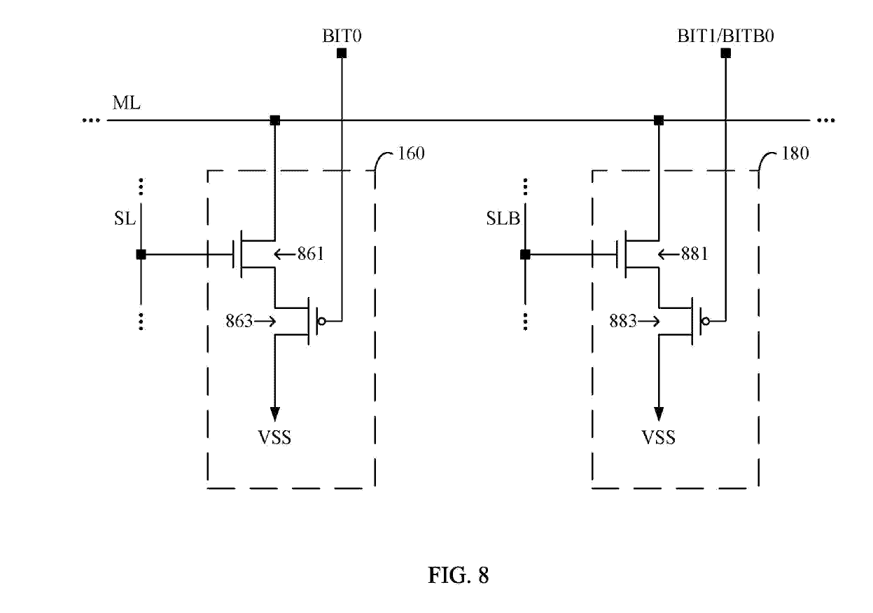

In the example shown in FIG. 8, the discharging circuit 160 includes an NMOS transistor 861 and a PMOS transistor 863, and the discharging circuit 180 includes an NMOS transistor 881 and a PMOS transistor 883. The NMOS transistor 861 has a drain coupled to the match line ML, a gate coupled to receive the searched bit SL, and a source coupled to a source of the PMOS transistor 863. The PMOS transistor 863 has a gate coupled to receive the stored bit BIT0 and a drain coupled to the source voltage VSS. Similarly, the NMOS transistor 881 has a drain coupled to the match line ML, a gate coupled to receive the searched bit SLB, and a source coupled to a source of the PMOS transistor 883. The PMOS transistor 883 has a gate coupled to receive the stored bit BIT1/BITB0 and a drain coupled to the source voltage VSS.

One of the advantages of the exemplary binary CAM cell 100 and TCAM cell 200 introduced above is that these cells have lower power consumption when performing search operations. Another of the advantage is that the cells have faster search speeds. These advantages may increase CAM/TCAM memory's performance and efficiency, making them more desirable and affordable.

In the foregoing detailed description, the invention has been described with reference to specific exemplary embodiments thereof. It will be evident that various modifications may be made thereto without departing from the spirit and scope of the invention as set forth in the following claims. The detailed description and drawings are, accordingly, to be regarded in an illustrative sense rather than a restrictive sense.

What is claimed is:

1. A TCAM cell, comprising:
a first storage circuit configured to provide a first stored bit;
a first discharging circuit, coupled to the first storage circuit, a first search line, and a match line, configured to either discharge or not discharge the match line according to the first stored bit provided by the first storage circuit and a first searched bit provided by the first search line, the first discharging circuit comprising:
a first PMOS transistor, having a gate coupled to receive one of the first stored bit and the first searched bit;
a second storage circuit configured to provide a second stored bit; and
a second discharging circuit, coupled to the second storage circuit, a second search line, and the match line, configured to either discharge or not discharge the match line according to the second stored bit provided by the second storage circuit and a second searched bit provided by the second search line, the second discharging circuit comprising:
a second PMOS transistor, having a gate coupled to receive one of the second stored bit and the second searched bit.

2. The TCAM cell of claim 1, wherein the gate of the first PMOS transistor is coupled to receive the first stored bit, the first discharging circuit further comprises a first NMOS transistor having a gate coupled to receive the first searched bit, the gate of the second PMOS transistor is coupled to receive the second stored bit, and the second discharging circuit further comprises a second NMOS transistor having a gate coupled to receive the second searched bit.

3. The TCAM cell of claim 2, wherein the first PMOS transistor has a source coupled to the match line and a drain coupled to a drain of the first NMOS transistor, the first NMOS transistor has a source coupled to a source voltage, the second PMOS transistor has a source coupled to the match line and a drain coupled to a drain of the second NMOS transistor, and the second NMOS transistor has a source coupled to the source voltage.

4. The TCAM cell of claim 2, wherein the first NMOS transistor has a drain coupled to the match line and a source coupled to a source of the first PMOS transistor, the first PMOS transistor has a drain coupled to a source voltage, the second NMOS transistor has a drain coupled to the match line and a source coupled to a source of the second PMOS transistor, and the second PMOS transistor has a drain coupled to the source voltage.

5. The TCAM cell of claim 1, wherein the gate of the first PMOS transistor is coupled to receive the first stored bit, the first discharging circuit further comprises a third PMOS transistor having a gate coupled to receive the first searched bit, the gate of the second PMOS transistor is coupled to receive the second stored bit, and the second discharging circuit further comprises a fourth PMOS transistor having a gate coupled to receive the second searched bit.

6. The TCAM cell of claim 5, wherein the first PMOS transistor has a source coupled to the match line and a drain coupled to a source of the third PMOS transistor, the third PMOS transistor has a drain coupled to a source voltage, the second PMOS transistor has a source coupled to the match line and a drain coupled to a source of the fourth PMOS transistor, and the fourth PMOS transistor has a drain coupled to the source voltage.

7. The TCAM cell of claim 5, wherein the third PMOS transistor has a source coupled to the match line and a drain coupled to a source of the first PMOS transistor, the first PMOS transistor has a drain coupled to a source voltage, the fourth PMOS transistor has a source coupled to the match line and a drain coupled to a source of the second PMOS transistor, and the second PMOS transistor has a drain coupled to the source voltage.

8. The TCAM cell of claim 1, wherein the gate of the first PMOS transistor is coupled to receive the first searched bit, the first discharging circuit further comprises a first NMOS transistor having a gate coupled to receive the first stored bit, the gate of the second PMOS transistor is coupled to receive the second searched bit, and the second discharging circuit further comprises a second NMOS transistor having a gate coupled to receive the second stored bit.

9. The TCAM cell of claim 8, wherein the first NMOS transistor has a drain coupled to the match line and a source coupled to a source of the first PMOS transistor, the first PMOS transistor has a drain coupled to a source voltage, the second NMOS transistor has a drain coupled to the match line and a source coupled to a source of the second PMOS transistor, and the second PMOS transistor has a drain coupled to the source voltage.

10. The TCAM cell of claim 8, wherein the first PMOS transistor has a source coupled to the match line and a drain coupled to a drain of the first NMOS transistor, the first NMOS transistor has a source coupled to a source voltage, the second PMOS transistor has a source coupled to the match line and a drain coupled to a drain of the second NMOS transistor, and the second NMOS transistor has a source coupled to the source voltage.

11. A binary CAM cell, comprising:
a storage circuit configured to provide a first stored bit and a second stored bit, wherein the second stored bit is a complimentary bit of the first stored bit;
a first discharging circuit, coupled to the storage circuit, a first search line, and a match line, configured to either discharge or not discharge the match line according to the first stored bit provided by the storage circuit and a first searched bit provided by the first search line, the first discharging circuit comprising:
a first PMOS transistor, having a gate coupled to receive one of the first stored bit and the first searched bit; and
a second discharging circuit, coupled to the storage circuit, a second search line, and the match line, configured to either discharge or not discharge the match line according to the second stored bit provided by the storage circuit and a second searched bit provided by the second search line, the second discharging circuit comprising:
a second PMOS transistor, having a gate coupled to receive one of the second stored bit and the second searched bit.

12. The binary CAM cell of claim 11, wherein the gate of the first PMOS transistor is coupled to receive the first stored bit, the first discharging circuit further comprises a first NMOS transistor having a gate coupled to receive the first searched bit, the gate of the second PMOS transistor is coupled to receive the second stored bit, and the second discharging circuit further comprises a second NMOS transistor having a gate coupled to receive the second searched bit.

13. The binary CAM cell of claim 12, wherein the first PMOS transistor has a source coupled to the match line and a drain coupled to a drain of the first NMOS transistor, the first NMOS transistor has a source coupled to a source voltage, the second PMOS transistor has a source coupled to the match line and a drain coupled to a drain of the second NMOS transistor, and the second NMOS transistor has a source coupled to the source voltage.

14. The binary CAM cell of claim 12, wherein the first NMOS transistor has a drain coupled to the match line and a source coupled to a source of the first PMOS transistor, the first PMOS transistor has a drain coupled to a source voltage, the second NMOS transistor has a drain coupled to the match line and a source coupled to a source of the second PMOS transistor, and the second PMOS transistor has a drain coupled to the source voltage.

15. The binary CAM cell of claim 11, wherein the gate of the first PMOS transistor is coupled to receive the first stored bit, the first discharging circuit further comprises a third PMOS transistor having a gate coupled to receive the first searched bit, the gate of the second PMOS transistor is coupled to receive the second stored bit, and the second discharging circuit further comprises a fourth PMOS transistor having a gate coupled to receive the second searched bit.

16. The binary CAM cell of claim 15, wherein the first PMOS transistor has a source coupled to the match line and a drain coupled to a source of the third PMOS transistor, the third PMOS transistor has a drain coupled to a source voltage, the second PMOS transistor has a source coupled to the match line and a drain coupled to a source of the fourth PMOS transistor, and the fourth PMOS transistor has a drain coupled to the source voltage.

17. The binary CAM cell of claim 15, wherein the third PMOS transistor has a source coupled to the match line and a drain coupled to a source of the first PMOS transistor, the first PMOS transistor has a drain coupled to a source voltage, the fourth PMOS transistor has a source coupled to the match line and a drain coupled to a source of the second PMOS transistor, and the second PMOS transistor has a drain coupled to the source voltage.

18. The binary CAM cell of claim 11, wherein the gate of the first PMOS transistor is coupled to receive the first searched bit, the first discharging circuit further comprises a first NMOS transistor having a gate coupled to receive the first stored bit, the gate of the second PMOS transistor is coupled to receive the second searched bit, and the second discharging circuit further comprises a second NMOS transistor having a gate coupled to receive the second stored bit.

19. The binary CAM cell of claim 18, wherein the first NMOS transistor has a drain coupled to the match line and a source coupled to a source of the first PMOS transistor, the first PMOS transistor has a drain coupled to a source voltage, the second NMOS transistor has a drain coupled to the match line and a source coupled to a source of the second PMOS transistor, and the second PMOS transistor has a drain coupled to the source voltage.

20. The binary CAM cell of claim 18, wherein the first PMOS transistor has a source coupled to the match line and a drain coupled to a drain of the first NMOS transistor, the first NMOS transistor has a source coupled to a source voltage, the second PMOS transistor has a source coupled to the match line and a drain coupled to a drain of the second NMOS transistor, and the second NMOS transistor has a source coupled to the source voltage.
